(19) United States
(12) Patent Application Publication
(10) Pub. No.: US 2010/0320187 A1
(43) Pub. Date: Dec. 23, 2010

(54) Heat Sink and Thermal Plate Apparatus for Electronic Components

(75) Inventors: David Griffin, Harvest, AL (US); Jeff Kusibab, Huntsville, AL (US); Glen Dace, Huntsville, AL (US)

Correspondence Address: SNR DENTON US LLP, P.O. BOX 061080, CHICAGO, IL, 60606-1080, US

(73) Assignee: DRS TEST & ENERGY MANAGEMENT, LLC, Huntsville, AL (US)

(21) Appl. No.: 12/486,647

(22) Filed: Jun. 17, 2009

(51) Int. Cl. H05B 1/02; H05K 7/20; F28F 7/00; H05B 3/00

(52) U.S. Cl. 219/209; 165/185; 219/494; 361/710; 361/705

(57) ABSTRACT

An apparatus for dissipating heat from and providing heat to electronic components includes a thermally conductive member having a surface configured to thermally couple with electronic components of an adjacent processing module, and a heating member embedded in the thermally conductive member.

### FIELD OF THE INVENTION

The present invention relates, generally, to heat sinks and, more particularly, to a heat sink and thermal plate apparatus configured to dissipate heat from and to provide heat to electronic components integral to an electronic assembly.

### BACKGROUND OF THE INVENTION

As faster circuitry is included in electronic devices, circuitry components tend to consume more power and, therefore, generate more heat. The amount of heat generated by the electrical components within enclosures of the electronic devices can cause the components to exceed their temperature ratings, especially when relying on convection and radiation heat transfer to dissipate the heat. With the ever increasing utilization of electronic devices in various technological fields, it has become increasingly important to provide for these devices enclosures which withstand harsh environmental conditions.

Harsh environmental conditions have been encountered in mobile applications, particularly land vehicles. Typically, environmental conditions are most severe for military vehicles such as tanks and other armored carriers which are required to perform under widely diverse climatic and operational conditions. For computer and electronic devices internal to these vehicles, it is critical that they be constructed and situated in such a way as to be able to withstand such conditions, including extreme temperatures.

Heat sinks and other conventional static electrical component cooling devices have typically been mounted to the top of heat generating components, to provide convection and radiation heat transfer. Fans have also been incorporated within the enclosures of these devices to increase their thermal capacity. However, conventional heat sinks are generally of no help when temperature conditions approach low temperature operating limits of these devices, and fans are typically subject to mechanical failure of their moving parts.

Therefore, a need exists that remedies the problems noted above and others previously experienced for enabling the use of electronic components in severe temperature conditions that are beyond their high and low temperature operating limits. These and other needs will become apparent to those of skill in the art after reading the present specification.

### SUMMARY OF THE INVENTION

The foregoing problems are solved and a technical advance is achieved by methods, systems and articles of manufacture consistent with the present invention, which provide an apparatus that enables the use of electronic components in severe temperature conditions that are beyond their high and low temperature operating limits.

In accordance with articles of manufacture consistent with the present invention, an embodiment of an apparatus for dissipating heat from and providing heat to electronic components includes a thermally conductive member having a surface configured to thermally couple with electronic components of an adjacent processing module, and a heating member embedded in the thermally conductive member.

In accordance with articles of manufacture consistent with the present invention, an embodiment of a severe environment enclosure for electronic components includes a chassis, first and second covers fixedly attachable to the chassis for sealing the enclosure, a processing assembly internal to the enclosure having a thermally conductive member and an adjacent processing module, the thermally conductive member having a surface configured to thermally couple with electronic components mounted on the adjacent processing module, and a heating member embedded in the thermally conductive member.

Other articles of manufacture, apparatuses, features, and advantages of the present invention will be or will become apparent to one with skill in the art upon examination of the following figures and detailed description. It is intended that all such additional systems, methods, features, and advantages be included within this description, be within the scope of the invention, and be protected by the accompanying claims.

### BRIEF DESCRIPTION OF THE DRAWINGS

The accompanying drawings, which are incorporated in and constitute a part of this specification, illustrate an implementation of the present invention and, together with the description, serve to explain the advantages and principles of the invention. In the drawings:

FIG. 1 is a perspective view of an exemplary embodiment of a mechanical assembly for housing electronic components in accordance of the present invention;

FIG. 2 is an exploded view of the mechanical assembly of FIG. 1 in accordance with the present invention;

FIG. 3 is a perspective view of an exemplary embodiment of a chassis of the mechanical assembly of FIG. 1 in accordance with the present invention;

FIG. 4 is a perspective view of an exemplary embodiment of an electronic package including a thermal plate/heat sink sandwiched between two circuit card assemblies in accordance with present invention;

FIG. 5 is an exploded view of the electronic package FIG. 4 in accordance with the present invention;

FIG. 6 is a perspective view of a thermal plate/heat sink of FIG. 4 in accordance with the present invention;

FIG. 7 is a perspective view of the thermal plate/heat sink with exemplary embodiments of a cartridge heater and a thermal switch in accordance with the present invention; and

FIG. 8 is graph illustrating changes in temperature at different locations of the thermal plate/heat sink after activation of the cartridge heater of FIG. 7 in accordance with the present invention.

### DETAILED DESCRIPTION OF THE PRESENTLY PREFERRED EMBODIMENTS

Reference will now be made in detail to an implementation consistent with the present invention as illustrated in the accompanying drawings. Wherever possible, the same reference numbers will be used throughout the drawings and the following description to refer to the same or like parts. As would be understood to one of ordinary skill in the art, certain components or elements of the heat sink and thermal plate (reverse heat sink) apparatus are not shown in the figures or specifically noted herein to avoid obscuring the invention.

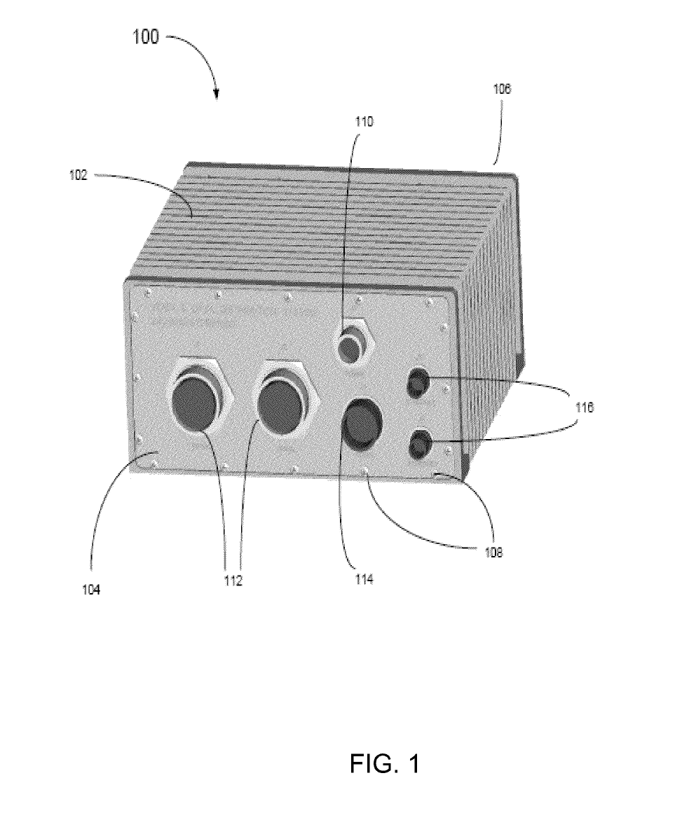

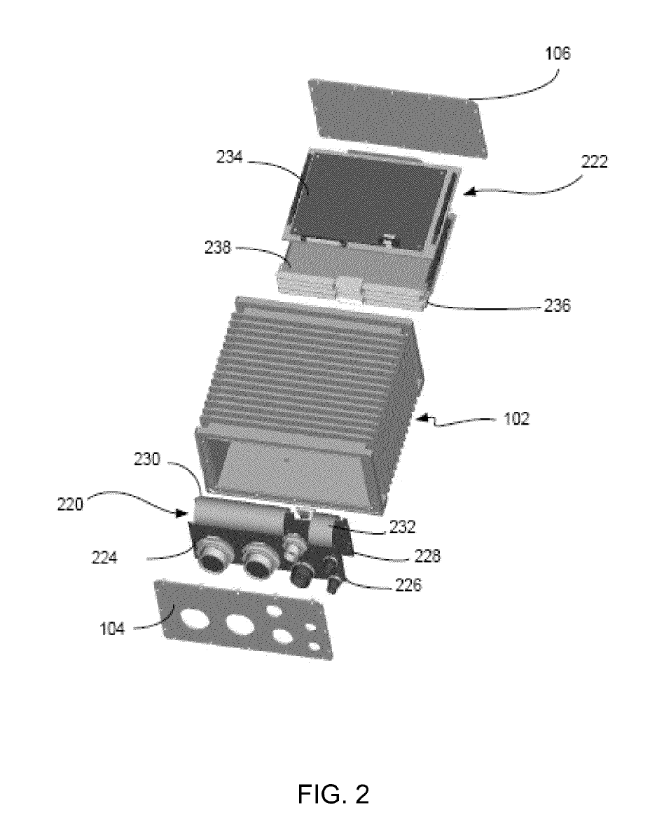

Referring to FIG. 1, a perspective view of a mechanical assembly or enclosure 100 for housing electronic components in accordance with an exemplary embodiment of the present invention is shown. The mechanical assembly 100 includes a rectangular parallelepiped housing or chassis 102, a front cover 104, and a back cover 106 (see FIG. 2). The front cover 104 and back cover 106 are shown securely fastened to the chassis 102 by means of a plurality of screw fasteners 108 to form an enclosure for internal components (not shown).

As best seen in FIGS. 1 and 2, the front cover 104 and the back cover 106 are flat substantially rectangular sheets, made preferably of an aluminum alloy or any other heat conducting material. Both covers 104 and 106 are provided near their peripheral edges with a plurality of fastener holes, and are recessed into chassis 102 to prevent Electromagnetic Interference (EMI) exit or infiltration. The front cover 104 is also provided with a plurality of holes configured to accommodate a multitude of connectors, such as a power connector 110, signal connectors 112 and 114, and Ethernet connectors 116, and the like. Moreover, indicators (not shown), comprising light, digital or analog displays, may also be provided on the front cover 104 to supply statuses and/or error messages related to the internal components.

Referring to FIG. 2, an exploded view of an exemplary embodiment of the mechanical assembly 100 is shown. In addition to the external elements discussed above, e.g. chassis 102, front cover 104 and back cover 106, the mechanical assembly 100 includes internally a backplane flexible assembly 220 and a power and processor assembly 222. The backplane flexible assembly 220 includes at a front end two separates rigid flex boards 224 and 226 for accommodating/attaching two sets of connectors introduced above, and at a back end another rigid flex board 228 for attaching power supply wiring harness, power supply I/O connectors, and interfaces to the power and processor assembly 222. The back end rigid flex board 228 is coupled to the two front end rigid flex boards 224 and 226 by two bookbinder-like flex sheets 230 and 232. The power and processor assembly 222 includes at a top end a power supply module 234 and at a bottom end two circuit card modules or assemblies (CCAs) 236 and 238 having a heat sink/thermal plate 240 therebetween. Since the backplane flex assembly 220 does not form part of the invention, no further description is provided.

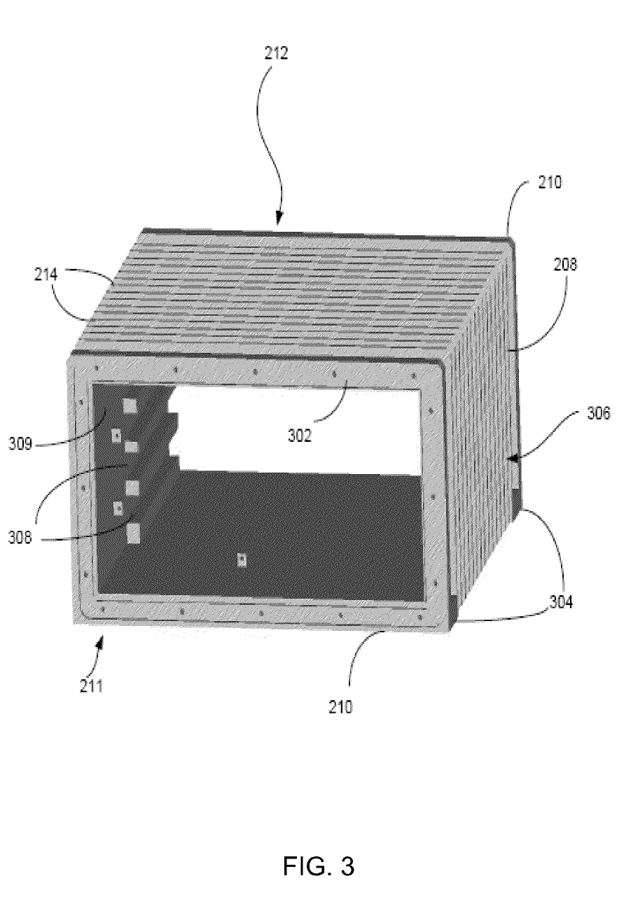

The rectangular parallelepiped chassis 102, as best seen in FIGS. 1, 2, and 3, is manufactured or milled to provide on all four sides a recessed area 208 surrounded by thickened border areas 210 at both a front end 211 and a back end 212. The recessed area 208 supports a series of integral and elongated fins 214, substantially parallel to one another and to the thickened border areas 210. The fins 214 provide surfaces designed to transfer heat away from the mechanical assembly 100. Alternately, the fins 214 may be arranged in a perpendicular direction to the thickened border areas 210, or any other direction that maximize heat transfer. The chassis 102 further includes on the outwardly facing surfaces of each one of the thickened border areas 210 a groove or an O-ring gasket channel 302 for watertight sealing the fastening of the front and back covers 104 and 106 to the chassis 102. As best shown in FIG. 3, the chassis 102 includes mounting points 304 located at or near the four lower corners of the side ends 306 of the chassis 102 to facilitate anchoring the mechanical assembly 100 in its installation site. Preferably, the construction design of the mechanical assembly 100 insures stiffness of structure and immobilization of internal components to enhance the assembly's immunity to vibration. Moreover, a plurality of horizontal slots 308 are provided on surfaces of internal side walls 309 of the chassis 102 for fixedly securing thereto the power and processor assembly 222.

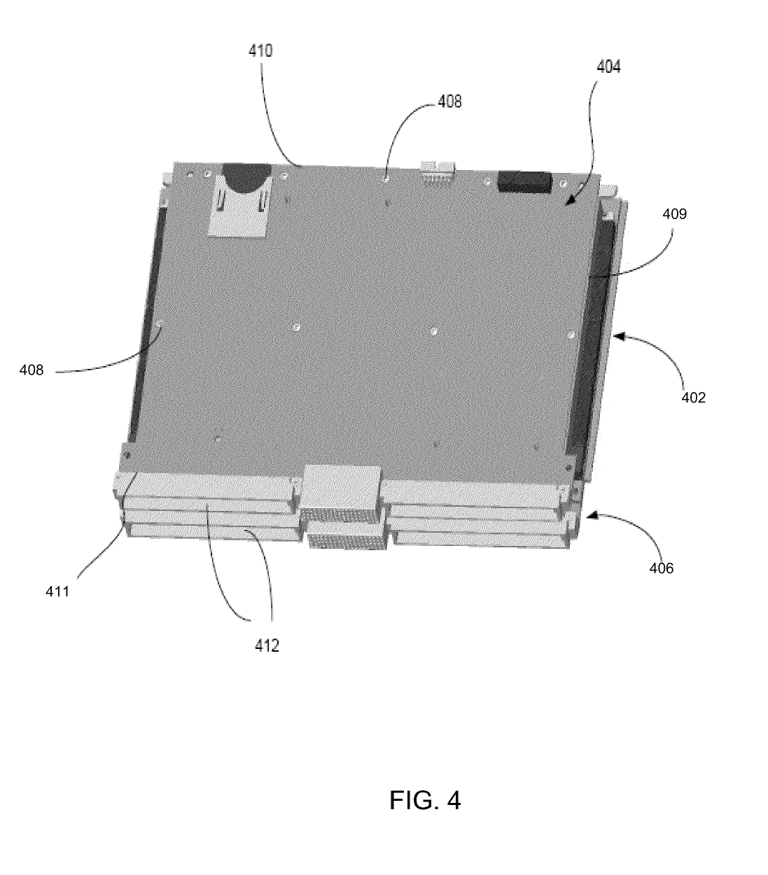

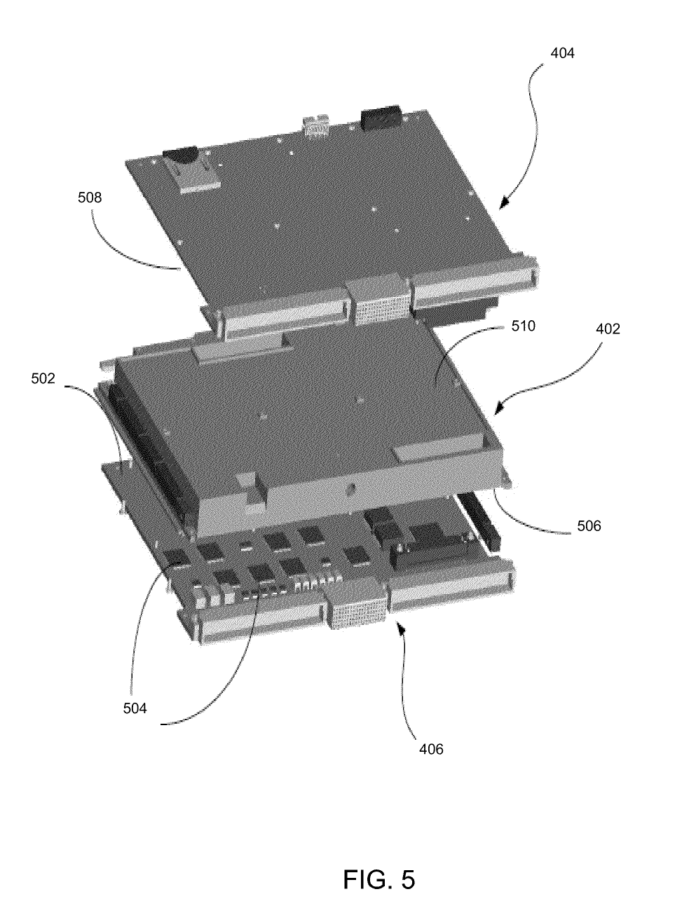

Now referring to FIGS. 4 and 5, an exemplary embodiment of a processor assembly or electronic package 400 comprised of the heat sink/thermal plate member 402 (hereafter referred to as heat sink/thermal plate) positioned between two processing CCAs 404 and 406 is shown. As shown in FIG. 4, upon assembly of the electronic package 400, the heat sink/thermal plate 402 is securely and rigidly attached to each of the two processing CCAs 404 and 406 by means of a plurality of fasteners 408. In known circuit configurations, printed circuit boards, such as CCAs, are typically equipped with electronic components on only one flat side. For this electronic package 400, the plurality of fasteners 408 are screwed into the CCAs 404 and 406 from their other or opposite sides. The number and spacing of the fasteners 408 are selected to insure maximum contact between each of surfaces of the thermal plate 402 and a correspondingly facing surface of each of the two processing CCAs 404 and 406. As shown, the upper processing CCA 404 has four fastener holes or mounting points, for receiving the fasteners 408, equally spaced between the side ends or edges 409 along its longitudinal middle and five additional fastener holes also equally spaced peripherally along a back end or edge 410. The lower processing CCA 406 is similarly perforated to provide similarly arranged fastener holes, as partially shown in FIG. 5. As further illustrated in FIG. 4, each of the two processing CCAs 404 and 406 has, at a respective front end 411, a set of interface connectors 412 for coupling to corresponding interfaces of the backplane flexible assembly 220.

As best seen in FIG. 5, the lower processing CCA 406, shown distant or removed from the heat sink/thermal plate 402, presents or exposes an upper side 502, equipped thereon with soldered electronic components 504, to a lower mating face or side 506 of the heat sink/thermal plate 402. Similarly, the upper processing CCA 404 exposes a lower side 508, also equipped thereon with electronic components 504, to an upper mating face or side 510 of the thermal plate 402. The mating faces 506 and 510 enable the thermally sensitive electronic components 504 of both processing CCAs 404 and 406 to be mounted substantially adjacent to, preferably in contact with, the heat sink/thermal plate 402.

In accordance with the invention, the heat sink/thermal plate 402 has a dual purpose, as a heat sink to dissipate heat to mitigate high temperatures conditions and as a heat source or heater to provide heat to mitigate low temperature conditions. The heat sink/thermal plate 402 is preferably made of a substantially heat conductive material, such as an aluminum alloy and the like, to maximize heat transfer away from and to the adjacently positioned thermally sensitive electronic components 504. For this purpose, the heat sink/thermal plate 402 is manufactured with mating faces 506 and 510 that substantially engage and contact top surfaces of electronic components 504 that protrude from the adjacent processing CCAs 404 and 406. To maximize direct thermal contact between these electronic components 504 and the heat sink/thermal plate 402, a thermally conductive adhesive (not shown) is applied to the top surfaces of these electronic components 504 and/or to the corresponding mating faces 506 and 510.

Upon assembly, when the processing CCAs 404 and 406 are brought in direct contact with the heat sink/thermal plate 402, there may still be surface irregularities that may reduce the contact area and may result in air gaps between opposing surfaces. The reduced contact area and air gaps may reduce the efficiency of the heat transfer. As such, one desirable aspect of the thermally conductive adhesive is the filling of substantially most, if not all, of the irregularities and air gaps, thereby maximizing the thermal coupling of the thermal plate 402 to each one of the processing CCAs 404 and 406. The thermally conductive adhesive may be made from any thermally conductive filler or binder, such as an epoxy. In the present invention, the use of a two-part epoxy provides desirable heat transfer properties. Generally, any known thermally conductive binder or combination of binders may be used to form the conductive adhesive. The addition of the thermally conductive adhesive may affect the mechanical and physical properties of the electronic package 400, but one skilled in the art can adjust formulas and/or amounts of the thermal adhesive, and potentially surface treatments to provide both desirable thermal conductivity and suitable performance of the electronic package 400.

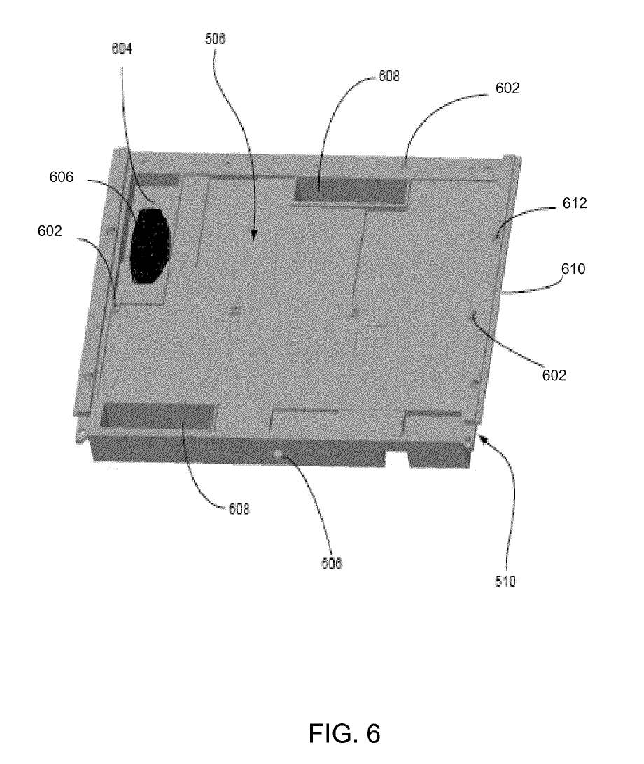

As best seen in FIG. 6, the heat sink/thermal plate 402 is provided with fastener holes 602 which are mounting points for the processing CCAs 404 and 406. The arrangement and spacing of the fastener holes 602, of course, match those of the fasteners 108, discussed above, to securely attach the heat sink/thermal plate 402 to the processing CCAs 404 and 406. Further, each of the mating faces 506 and 510 includes cavities or depressions 604 to fittingly accept the corresponding electronic components 504. These cavities 604 are tailored to accommodate the electronic elements 504 and the conductive adhesive 606. Moreover, through holes 608 are formed in the heat sink/thermal plate 402 to enable proper coupling of interface connectors (not shown) of the two processing CCAs 404 and 406.

In order to provide a desirable thermal interface to the chassis 102, the heat sink/thermal plate 402 is further equipped with flanges or lips 610 along each of its width sides. These flanges 610 are also drilled or perforated to provide fastener holes 612 to securely affix the heat sink/thermal plate 402 to a corresponding set of the slots 308. Additionally, circuit board retainers or wedge-locks, configured to protect circuit boards from thermal and mechanical damage in harsh or severe environments where convection cooling is desired, are inserted and adjusted in slots 308 to provide a substantially uniform clamping force on the flanges 610 across the length of the slots 308. The heat sink/thermal plate 402, via the affixed flanges 610, provides an efficient thermal path to the chassis 102 which is externally covered with fins 214 to dissipate heat to the ambient air. This arrangement efficiently cools the thermally sensitive electronic components 504 when subjected to high temperature conditions, but also exposes these electronic components 504 to extreme or severe temperature conditions that are beyond their low temperature operating limits.

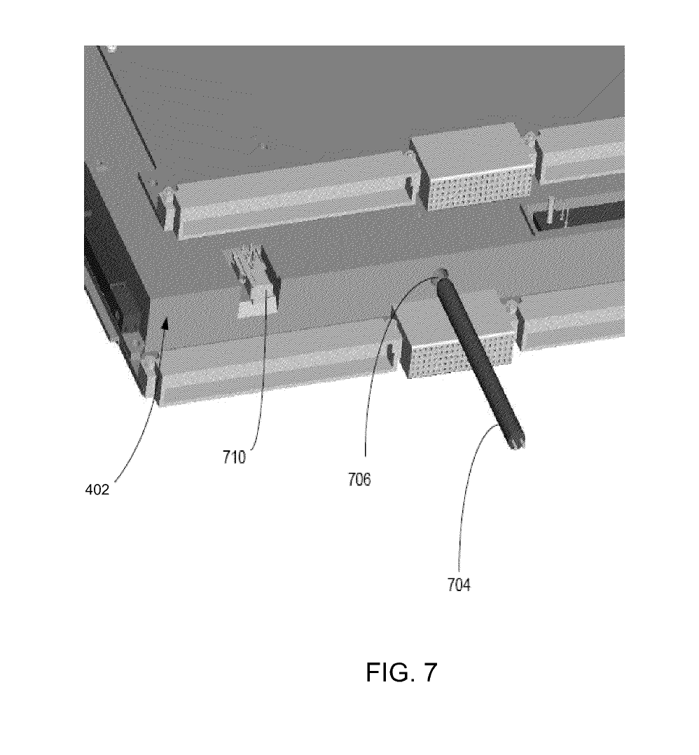

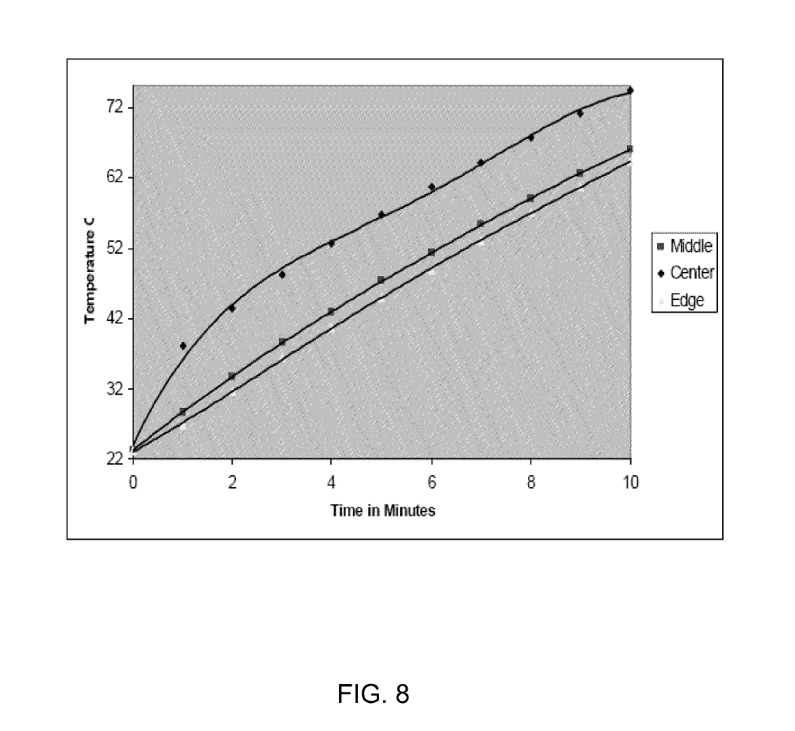

The low temperature exposures of the electronic components 504 are mitigated through the use of cartridge heater 704, embedded or buried in a hole 706 formed into and perpendicularly to a front end side of the heat sink/thermal plate 402, as shown in FIG. 7. The hole 706 is preferably centrally located within the heat sink/thermal plate 402 for a balanced distribution of the heat generated by the cartridge heater 704, which held in place with a setscrew (not shown) screwed into the thermal plate at a setscrew location 708. A thermal switch 710, mounted to one of the processing CCAs 404 and 406, is configured to control the application of power to the cartridge heater 704. That is, the thermal switch 710 energizes or activates via a power supply (not shown) the cartridge heater 704 when a low temperature operating limit of one of the processing CCAs 404 and 406 or of one of the electronic components 504 is reached. Preferably, the cartridge heater 704 is activated when operating temperatures are below zero degrees Celsius (0° C.), for example. As shown in FIG. 8, temperatures detected or sensed at different locations of the heat sink/thermal plate 402, e.g. middle, center and edge, increase substantially linearly from 0° C. to at least about 62° C. about ten minutes after activation of the cartridge heater 704.

In accordance with the invention, a cooling path for processing boards or CCAs of an electronic package is established from the top surfaces of their electronic components through a thermal adhesive into an aluminum heat sink/thermal plate which is thermally clamped into a chassis equipped with external fins to dissipate heat to the ambient air, thereby lowering the operating temperature to a desired level. Moreover, a cartridge heater, buried into the heat sink/thermal plate, is activated to raise the operating temperature of the electronic components to another desired level.

While various embodiments of the present invention have been described, it will be apparent to those of skill in the art that many more embodiments and implementations are possible that are within the scope of this invention. Accordingly, the present invention is not to be restricted except in light of the attached claims and their equivalents.

1. An apparatus for dissipating heat from and providing heat to electronic components, comprising:
a thermally conductive member having a surface configured to thermally couple with electronic components of an adjacent processing module; and
a heating member embedded in the thermally conductive member.

2. The apparatus of claim 1, further comprising a thermally conductive adhesive material applied to the thermally conductive member and/or to the electronic components to improve thermal contact between the thermally conductive member and the electronic components.

3. The apparatus of claim 1, further comprising a thermal switch connecting the heating member to a power source for controlling application of power to the heating member.

4. The apparatus of claim 4, wherein the power is applied to the heating member when the thermal switch detects an operating temperature that is below a predetermined level.

5. The apparatus of claim 4, wherein the thermal switch is connected to the adjacent module.

6. The apparatus of claim 1, wherein the thermally conductive member has another surface configured to thermally couple with electronic components of another adjacent processing module.

7. A severe environment enclosure for electronic components, comprising:
a chassis;
first and second covers fixedly attachable to the chassis for sealing the enclosure;
a processing assembly internal to the enclosure having a thermally conductive member and an adjacent processing module, the thermally conductive member having a surface configured to thermally couple with electronic components mounted on the adjacent processing module; and
a heating member embedded in the thermally conductive member.

8. The severe environment enclosure of claim 7, wherein the chassis has fins formed on an external surface thereof for dissipating heat to surrounding ambient air.

9. The severe environment enclosure of claim 7, wherein the thermally conductive member is thermally coupled to the chassis to provide a thermal path from the electronic components to the chassis.

10. The severe environment enclosure of claim 7, further comprising a thermally conductive adhesive material applied to the thermally conductive member and/or to the electronic components to improve thermal contact between the thermally conductive member and the electronic components.

11. The severe environment enclosure of claim 7, further comprising a thermal switch connecting the heating member to a power source for controlling application of power to the heating member.

12. The severe environment enclosure of claim 12, wherein the power is applied to the heating member when the thermal switch detects an operating temperature that is below a predetermined level.

13. The severe environment enclosure of claim 7, wherein the thermal switch is connected to the adjacent module.

14. The severe environment enclosure of claim 7, wherein the thermally conductive member is configured to thermally couple with electronic components of another adjacent processing module via another surface.
